(19) United States
(12) Patent Application Publication
(10) Pub. No.: US 2009/0032668 A1
(43) Pub. Date: Feb. 5, 2009

(54) ADJUSTABLY-TILTABLE SUPPORTING APPARATUS AND DISPLAY WITH THE SAME

(75) Inventors: Yi-Yen Lin, Taoyuan (TW); Hsiang-Chun Lu, Taoyuan (TW); Chien-Hua Sui, Taoyuan (TW)

Correspondence Address: HOFFMAN WARNICK LLC, 75 STATE STREET, 14TH FLOOR, ALBANY, NY, 12207, US

(73) Assignee: BenQ Corporation, Taipei (TW)

(21) Appl. No.: 11/933,452

(22) Filed: Nov. 1, 2007

(30) Foreign Application Priority Data
Aug. 1, 2007 (TW) 09612821

(51) Int. Cl. A47F 5/12; A47B 96/07; H05K 5/00; A47F 7/00

(52) U.S. Cl. 248/371; 248/274.1; 248/309.1; 361/681

(57) ABSTRACT

The invention provides an adjustably-tiltable supporting apparatus which is capable of supporting an object, and it includes a shelf member, a supporting member, a friction device, and a resilient member. When the tilt of the object is adjusted, the supporting member rotates relative to the shelf member so that the outer side of supporting member slides relative to a friction member of the friction device to generate a friction which balances a difference between a torque generated by the weight of the object and an elastic force generated by the resilient member so as to fix the tilt.

### BACKGROUND OF THE INVENTION

1. Field of the Invention

The invention relates to an adjustably-tiltable supporting apparatus and an adjustably-tiltable display, and more particularly, to an adjustably-tiltable supporting apparatus and an adjustably-tiltable display utilizing the elastic force and the lateral friction of resilient members instead of the angle-adjustment function of a conventional hinge, so as to reduce required metal materials and number of parts to lower the manufacturing cost.

2. Description of the Prior Art

For the time being, most adjustably-tiltable supporting apparatuses utilize complicated parts such as hinges to pivotally connect an object with a base so that the object can be rotated and fixed relative to the base. In prior arts, the supporting apparatus only provides friction at the connecting points between the object and the base such that the structural design is not strong enough.

Besides, most supporting apparatuses of prior arts utilize a great deal of parts and metal materials, and they are also assembled with complication. And, that kind of supporting apparatus occupies much package space and thus increases the transportation cost. In sum, hinge assembly of the prior art requires many parts and then increases the size of packages; consequently, the total manufacturing cost is raised as well.

Accordingly, a scope of the invention is to provide an adjustably-tiltable supporting apparatus and an adjustably-tiltable display to solve aforesaid problems.

### SUMMARY OF THE INVENTION

A scope of the invention is to provide an adjustably-tiltable supporting apparatus and an adjustably-tiltable display which utilize an outer side of a supporting member to slide on a frictional member to generate a friction, and the friction balances a torque generated by the weight of the object and an elastic force generated by a compressed resilient member, so as to fix the tilt of the object. Thereby, conventional hinges are replaced by the resilient members such that metal materials and number of parts are decreased so as to lower the total manufacturing cost.

According to an embodiment of the invention, an adjustably-tiltable supporting apparatus is capable of supporting an object. The adjustably-tiltable supporting apparatus includes a shelf member, a supporting member, a friction device, and a first resilient member. The shelf member has an inner side and the supporting member has an outer side facing the inner side of the shelf member. The supporting member is pivotally mounted on the shelf member, and the object is capable of being mounted on the supporting member. The friction device includes a friction member. The friction device is adjustably disposed on the inner side of the shelf member, and, via the friction member, urges against the outer side of the supporting member. The first resilient member is compressed between the shelf member and the supporting member. When the tilt of the object is adjusted, the supporting member rotates relative to the shelf member such that the outer side of the supporting member slides on the friction member to generate a friction which balances a torque generated by the weight of the object and an elastic force generated by the first resilient member so as to fix the tilt. According to another embodiment of the invention, an adjustably-tiltable display includes a display apparatus, a base, a shelf member, a supporting member, a friction member, and a first resilient member. The shelf member has an inner side and is mounted on the base. The supporting member has an outer side facing the inner side of the shelf member. The supporting member is pivotally mounted on the shelf member, and the displaying apparatus is mounted on the supporting member. The friction device includes a friction member. The friction device is adjustably disposed on the inner side of the shelf member, and, via the friction member, urges against the outer side of the supporting member. The first resilient member is compressed between the shelf member and the supporting member. When the tilt of the displaying apparatus is adjusted, the supporting member rotates relative to the shelf member such that the outer side of the supporting member slides on the friction member to generate a friction which balances a torque generated by the weight of the displaying apparatus and an elastic force generated by the first resilient member so as to fix the tilt.

Therefore, according to the invention, the adjustably-tiltable supporting apparatus and the adjustably-tiltable display utilize an outer side of a supporting member to slide on a frictional member to generate a friction, and the friction balances a torque generated by the weight of the object, such as the displaying apparatus, and an elastic force generated by a compressed resilient member, so as to fix the tilt of the object. Thereby, conventional hinges are replaced by the resilient members, such that metal materials and number of parts are decreased so as to lower the total manufacturing cost.

The advantage and spirit of the invention may be understood by the following recitations together with the appended drawings.

### BRIEF DESCRIPTION OF THE APPENDED DRAWINGS

FIG. 1 is an explosive view of the adjustably-tiltable supporting apparatus according to an embodiment of the invention.

FIG. 2 is an assembled view of the adjustably-tiltable supporting apparatus shown in FIG. 1.

FIG. 3A shows the adjustably-tiltable display according to another embodiment of the invention as it tilts forwardly.

FIG. 3B shows the adjustably-tiltable display according to the embodiment of the invention as it tilts backwardly.

### DETAILED DESCRIPTION OF THE INVENTION

The invention provides an adjustably-tiltable supporting apparatus and the adjustably-tiltable display which utilize an outer side of a supporting member to slide on a frictional member to generate a friction, and the friction balances a torque generated by the weight of the object and an elastic force generated by a compressed resilient member, so as to fix the tilt of the object. Thereby, conventional hinges are replaced by the resilient members, such that metal materials and number of parts are decreased so as to lower the total manufacturing cost. The spirit and feature of the present invention will be described in detail by the following preferred embodiments.

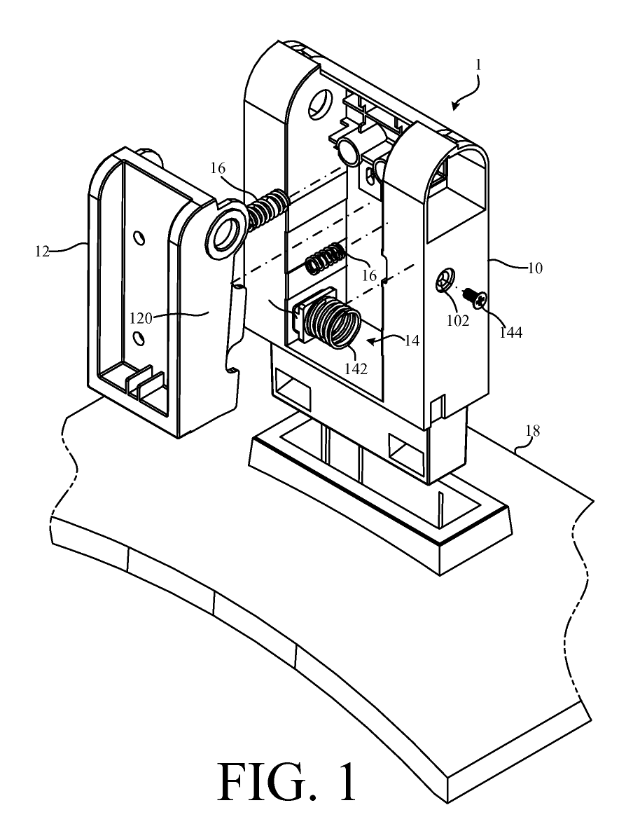

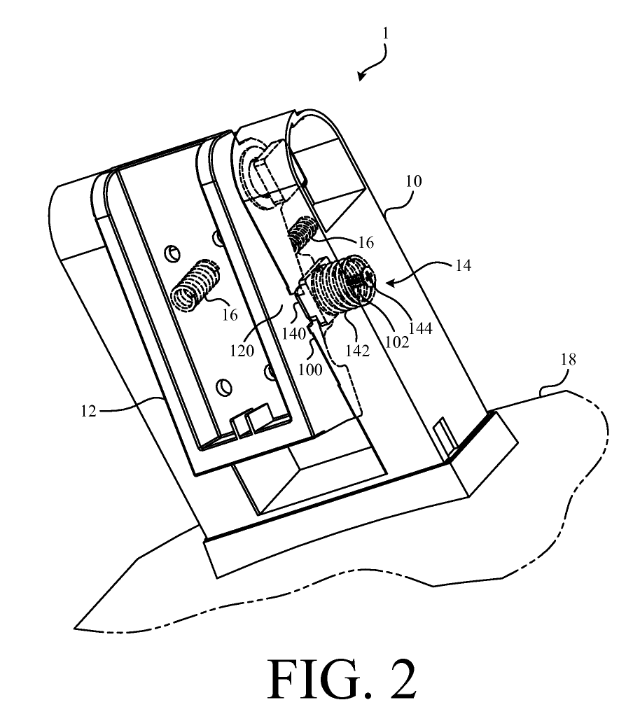

Please refer to FIG. 1 and FIG. 2. FIG. 1 is an explosive view of the adjustably-tiltable supporting apparatus 1 according to an embodiment of the invention. FIG. 2 is an assembled view of the adjustably-tiltable supporting apparatus 1 shown in FIG. 1. In the embodiment, the adjustably-tiltable supporting apparatus 1 can support an object. As shown in FIG. 1 and FIG. 2, the adjustably-tiltable supporting apparatus 1 includes a shelf member 10, a supporting member 12, a friction device 14, and a first resilient member 16.

The shelf member 10 has an inner side 100 and the supporting member 12 has an outer side 120 facing the inner side 100 of the shelf member 10. The supporting member 12 is pivotally mounted on the shelf member 10, and the object is capable of being mounted on the supporting member 12. In real applications, the object can be, but not limited to, a display.

The friction device 14 includes a friction member 140. The friction device 14 is adjustably disposed on the inner side 100 of the shelf member 10, and, via the friction member 140, urges against the outer side 120 of the supporting member 12.

The first resilient member 16 is compressed between the shelf member 10 and the supporting member 12. In real applications, the first resilient member 16 can be, but not limited to, a compression spring or a torsion spring.

When the tilt of the object is adjusted, the supporting member 12 rotates relative to the shelf member 10 such that the outer side 120 of the supporting member 12 slides on the friction member 140 to generate a friction which balances a torque generated by the weight of the object and an elastic force generated by the first resilient member 16 so as to fix the tilt. It is noticeable that due to the effect of the first resilient member 16 and the friction member 140, the user can easily adjust the tilt of the object, and the object can be fixed at any tilt in an adjustable range.

In real applications, the inner side 100 of the shelf member 10 has a formed-through screw hole 102. The friction device 14 further includes a second resilient member 142 and a screw 144 adapted to the screw hole 142. The second resilient member 142 is disposed between the friction member 140 and the inner side 100 of the shelf member 10. The screw 144 is screwed into the screw hole 102 and urges against the second resilient member 142 such that the compression of the second resilient member 142 is adjusted by the screw 144 to adjust the friction. By adjusting the friction, the tilt of the object can be adjusted more smoothly. In real applications, the second resilient member 142 can be, but not limited to, a compression spring.

In real applications, the adjustably-tiltable supporting apparatus 1 can further include a base 18, and the shelf member 10 can be mounted on the base 18. Furthermore, the shelf member 10 can also be mounted on a structural member (not shown in FIG. 1) such as a wall.

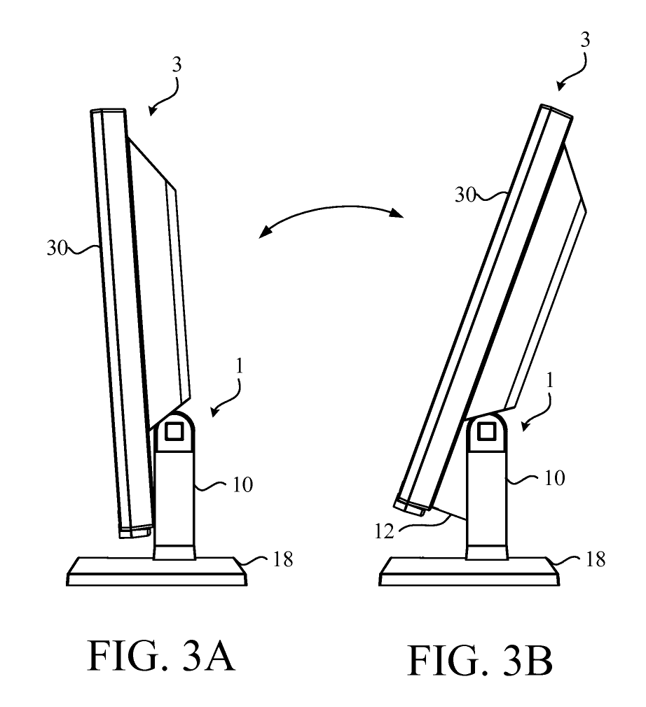

Please refer to FIG. 3A and FIG. 3B along with FIG. 1 and FIG. 2. FIG. 3A shows the adjustably-tiltable display 3 according to another embodiment of the invention as it tilts forwardly. FIG. 3B shows the adjustably-tiltable display 3 according to the embodiment of the invention as it tilts backwardly. In the embodiment, the adjustably-tiltable display 3 includes a displaying apparatus 30, the base 18, the shelf member 10, the supporting member 12, the friction member 14, and the first resilient member 16.

In the embodiment, the adjustably-tiltable display 3 utilizes the adjustably-tiltable supporting apparatus 1 shown in FIG. 1 and FIG. 2. The infrastructure of the adjustably-tiltable supporting apparatus 1 is described in FIG. 1, FIG. 2 and the corresponding description mentioned above. It should be noted that the object described above can be the displaying apparatus 30 shown in FIG. 3A and FIG. 3B. When the tilt of the displaying apparatus 30 is adjusted, the supporting member 12 rotates relative to the shelf member 10 such that the outer side 120 of the supporting member 12 slides on the friction member 140 to generate a friction which balances a torque generated by the weight of the displaying apparatus 30 and an elastic force generated by the first resilient member 16 so as to fix the tilt.

With the example and explanations mentioned above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. An adjustably-tiltable supporting apparatus, capable of supporting an object, comprising:
a shelf member having a inner side;
a supporting member having a outer side facing the inner side of the shelf member, the supporting member being pivotally mounted on the shelf member, the object being capable of being mounted on the supporting member;
a friction device comprising a friction member, the friction device being adjustably mounted on the inner side of the shelf member and, via the friction member, urging against the outer side of the supporting member; and
a first resilient member compressed between the shelf member and the supporting member;
wherein when the tilt of the object is adjusted, the supporting member rotates relative to the shelf member such that the outer side of supporting member slides on the friction member to generate a friction which balances a torque generated by the weight of the object and an elastic force generated by the first resilient member so as to fix the tilt.

2. The adjustably-tiltable supporting apparatus of claim 1, wherein the inner side of the shelf member has a formed-through screw hole, the friction device further comprises a second resilient member and a screw adapted to the screw hole, the second resilient member is disposed between the friction member and the inner side of the shelf member, the screw is screwed into the screw hole and urges against the second resilient member such that the compression of the second resilient member is adjusted by the screw to adjust the friction.

3. The adjustably-tiltable supporting apparatus of claim 2, wherein the second resilient member is a compression spring.

4. The adjustably-tiltable supporting apparatus of claim 1, wherein the first resilient member is one of a compression spring and a torsion spring.

5. The adjustably-tiltable supporting apparatus of claim 1, wherein the object is a display.

6. The adjustably-tiltable supporting apparatus of claim 1, further comprising a base which the shelf device is mounted on.

7. The adjustably-tiltable supporting apparatus of claim 1, wherein the shelf device is capable of being mounted on a structural member.

8. An adjustably-tiltable display, comprising:
a displaying apparatus;
a base;
a shelf member having a inner side, the shelf member being mounted on the base;
a supporting member having a outer side facing the inner side of the shelf member, the supporting member being pivotally mounted on the shelf member, the displaying apparatus being mounted on the supporting member;
a friction device comprising a friction member, the friction device being adjustably mounted on the inner side of the shelf member and, via the friction member, urging against the outer side of the supporting member; and
a first resilient member compressed between the shelf member and the supporting member;
wherein when the tilt of the displaying apparatus is adjusted, the supporting member rotates relative to the shelf member such that the outer side of supporting member slides on the friction member to generate a friction which balances a torque generated by the weight of the displaying apparatus and an elastic force generated by the first resilient member so as to fix the tilt.

9. The adjustably-tiltable display of claim 8, wherein the inner side of the shelf member thereon has a formed-through screw hole, the friction device further comprises a second resilient member and a screw adapted to the screw hole, the second resilient member is disposed between the friction member and the inner side of the shelf member, the screw is screwed into the screw hole and urges against the second resilient member such that the compression of the second resilient member is adjusted by the screw to adjust the friction.

10. The adjustably-tiltable display of claim 9, wherein the second resilient member is a compression spring.

11. The adjustably-tiltable display of claim 8, wherein the first resilient member is one of a compression spring and a torsion spring.
